(19) United States
(12) Patent Application Publication
(10) Pub. No.: US 2004/0218768 A1
(43) Pub. Date: Nov. 4, 2004

(54) Method for volume control of an audio reproduction and device for carrying out said method

(76) Inventors: Dmitry Vyacheslavovich Zhurin, Moscow (RU); Alexander Vitalievich Smirnov, Moscow (RU)

Correspondence Address: D Zhurin, Y Vladagin, 6038 Tyndall Avenue, Bronx, NY, 10471, US

(21) Appl. No.: 10/469,752

(22) PCT Filed: Feb. 27, 2002
(86) PCT No.: PCT/RU02/00064

(30) Foreign Application Priority Data
Mar. 5, 2001 (RU) 2001105990

(51) Int. Cl. H03G 3/00

(52) U.S. Cl. 381/107; 381/104

(57) ABSTRACT

The method for volume control comprises pre-setting of a higher and lower volume levels prior to the volume control; adjusting the volume at the lower pre-set level upon the detection of human voices, and at the higher pre-set level in the absence of human voices. Analysis and a control unit of the volume control system is operative to form at its output a control signal providing the volume decrease in the audio reproducing unit to the lower pre-set level upon the detection of human voices in accordance with a first pre-set time function, and the volume to the upper pre-set level in the absence of human voices in accordance with a second pre-set time function.

### THE FIELD OF THE INVENTION

The invention relates to radio-electronics and more particularly to sound-reproducing devices. It can be used in designing audio reproducing devices with automatic volume control depending on the presence of other audio sources as well as in designing remote control devices.

### BACKGROUND OF THE INVENTION

U.S. Pat. No. 5,615,270, 1997, to Miller et al, discloses a method for volume control. In accordance to this method, during the audio reproduction noises are detected within a monitored space and in accordance to the results of the detection the volume of audio reproduction is adjusted.

The method according to Miller provides the volume increase, if noises are detected by a sensing microphone, and ensures an optimal music level, for example inside a car. When the noise level increases, the volume of the sound reproduction increases. When the noise level decreases, the volume is also decreased.

The limitation of the above method is its limited functionality. The method according to Miller does not include the detection of human voices in the monitored area. In the result, the people conversation inside the area is perceived as a noise and the volume of audio reproduction increases. So, users need to adjust the volume manually to have comfortable conditions for the conversation.

The most close to the claimed method is the method of volume control disclosed in U.S. Pat. No. 4,677,389, 1987, to Op de Beek et al. According to this method, during the audio reproduction it is checked, if human voices are detected within a monitored area and the volume of the audio reproduction is adjusted according to the results of the detection.

The method according to Op de Beek provides the volume control of the audio reproduction, for example of music, depending on the noise level. If the observed signal from the sound sensor comprises components created by sounds other than speech, the volume of audio reproduction increases so that the level of the audio reproduction is sufficient. If it is detected that the observed signal from the sound sensor comprises components of speech, the volume level remains the same not to impede the conversation.

The limitation of the method according to Op de Beek is also its limited functionality. If speech is detected within a monitored area, the volume level does not change. However, if the volume level has been set rather high, which is natural if users are listening to music, the conversation becomes difficult. To create conditions suitable for the conversation, the user has to decrease the audio reproduction volume manually, and after the conversation is over—to resume the initial volume level good for listening to music.

U.S. Pat. No. 5,615,270, 1997, to Miller and et al, discloses a sound-reproducing device comprising a sound-reproducing unit, connected with a sound signal source, a sound sensor, and an analyzing and control unit, connected with the sound sensor.

The above device provides the volume increase upon detection of noises by sound sensor and can provide an optimal volume level of music reproduction, for example inside the car. If the noise level increases, the music level increases. If the noise level decreases, the volume level of music reproduction decreases.

However, the system according to Miller also has some limitations. The conversation of people within the monitored by the sound sensor area is perceived as a noise and the audio reproduction volume increases. To create conditions suitable for the conversation, the user has to adjust volume manually.

The most close to the claimed system is a volume control system disclosed in U.S. Pat. No. 4,677,389, 1987, to Op de Beek. The system according to Op de Beek comprises a sound-reproducing unit, connected with a sound signal source, a sound sensor, and an analysis and control unit, connected with the sound sensor, and with the sound-reproducing unit. The analysis and control unit is operative to detect features generated by people in the observed signal received from sound sensor an to form on its output a control signal depending on the result of the detection of human voice features.

The system according to Op de Beek analyses an observed signal from the sound sensor and controls the volume of the audio reproduction, for example of music, depending on the presence of various noises and their volume. When components generated by some noise, but not human speech are detected in the observed signal, the volume level of the reproduced sound increases so that to provide suitable audibility of the sound reproduction against the background noise. When components generated by human speech are detected in the observed signal, the volume level of the reproduced sound remains the same so that not to impede the conversation.

The above system also has its limitations. If speech is detected, the volume level of the audio reproduction does not change. However, if the volume level has been set rather high, which is natural if users are listening to music, the conversation becomes difficult. To create conditions suitable for the conversation, the user has to decrease the audio reproduction volume manually, and after the conversation is over—to resume the initial volume level good for listening to music.

U.S. Pat. No. 5,386,478, 1995, to Plunkett, discloses a remote control device for audio equipment comprising a sound sensor, an analysis and control unit, a command former unit, and a transmitter connected consecutively. This remote control device receives and analyzes sounds generated by the sound-reproducing equipment and by forming and transmitting the corresponding remote control commands provides an optimal sound features in the point of the user location.

The limitation of the above remote control device is its limited functionality, as it cannot detect human voices and speech in particular within the monitored area and control the volume of audio reproduction depending on the results of such detection.

The most close to the claimed remote control device is the device disclosed in U.S. Pat. No. 5,267,323, 1993, to Kimura, comprising a sound sensor, an analysis and control unit, a command forming unit, and a transmitter connected consecutively.

The above device can perceive human voices and recognize voice commands and then form corresponding commands and transmit them to the remotely controlled equipment.

The limitation of the remote control device according to Kimura is that it cannot control the audio reproduction volume depending on the detection of human voices and speech in particular within a monitored area.

### OBJECTS AND SUMMARY OF THE INVENTION

It is an object of the present invention to provide a method of volume control and devices for its implementation that would provide an automatic volume decrease to a low preset level upon detecting human voices within a monitored area and an automatic volume increase to a high preset level upon the absence of human voices within a monitored area.

The method of volume control according to the present invention comprises the steps of defining of a high preset volume level and a second preset volume level; checking for human voice presence in a monitored area during the audio reproduction; and controlling of volume of the audio reproduction so that the volume is set at the low preset volume level upon detecting human voices, and is set to the high preset volume level, if no human voices are detected. The volume change from the high preset level to the low preset level is made in accordance to a first predetermined function of time, and the volume change from the low preset level to the high preset level is made in accordance to a second predetermined function of time.

Further, in the present invention method, the first and second predetermined functions of time comprise at least one time segment, during which the volume level does not change and following it another segment of time, during which the volume changes monotonically.

Further, in the present invention method, at least one of the first and second predetermined functions of time is formed depending on parameters of detected human voice sounds.

Further, in the present invention method, the checking for human voice presence comprises a conversion of the sounds within the monitored area into an observed signal and checking for speech features in the observed signal.

Further, in the present invention method, the checking for a human voice presence comprises a conversion of sounds within the monitored area into an observed signal, a conversion of sounds within another area into an additional observed signal, and a comparison of the observed signal with the additional observed signal.

Further, in the method according to the present invention, the comparison of the observed signal with the additional observed signal comprises a detection of an envelope of the observed signal; a detection of an envelope of the additional observed signal; a first measuring of a part of the envelope of the observed signal in a predetermined frequency range; a second measuring of a part of the envelope of the additional observed signal in the predetermined frequency range; a comparison of the results of the first measuring and the second measuring.

The method according to the present invention can be realized with a system of volume control, comprising a sound-reproducing unit connected with a sound signal source; a sound sensor; an analysis and control unit, connected with the sound sensor and with the sound-reproducing unit. The analysis and control unit is operative to detect human voice features in a signal received from the sound sensor, and to form a control signal providing the volume decrease in the sound-reproducing unit according to a first function of time to a preset low volume level upon detecting human voice features, and the volume increase in the sound-reproducing unit according to a second function of time to a preset high volume level, when no human voice features are detected.

Further, in the claimed system the sound sensor can be operative to control the sound level within a monitored area.

Further, in the claimed system, the analysis and control unit comprises consecutively connected a feature detection unit, a measuring unit, and a control signal former.

Further, the feature detection unit comprises consecutively connected a band-pass filter, a detector, and a low-pass filter.

Further, the analysis and control unit in the present invention is constructively displaced in a separate from the sound-reproducing unit housing.

Further, in the claimed system, the housing of said analysis and control unit is the housing of a remote control device of the sound-reproducing unit.

Further, the analysis and control unit in the present invention system is additionally connected with the sound signal source and is operative to compare a signal received from the sound sensor to a signal received from the sound signal source, thereby to detect human voice features in the signal received from the sound sensor.

Further, the analysis and control unit in the claimed system comprises consecutively connected a subtraction unit, a feature detection unit, a measuring unit, and a control signal former.

Further, the feature detection unit in the present invention system comprises consecutively connected an envelope detector, a band-pass filter, a detector, and a low-pass filter.

Further, the present invention system comprises an additional sound sensor, connected with said analysis and control unit, which is additionally operative to detect human voice features in the signal received from the sound sensor by comparing the signal with the signal received from the additional sound sensor.

Further, the analysis and control unit in the present invention system comprises a first and second detectors, a first and second measuring units, a comparison unit, and a control signal former. The first measuring unit is connected with the first detector, the second measuring unit is connected with the second detector. The comparison unit is connected with the first measuring unit, the second measuring unit and the control signal former.

Further, in the present invention system, each of the first measuring unit and the second measuring unit comprises a band-pass filter, a first and second detectors, and a subtraction unit. The input of the measuring unit is connected with the second detector and band-pass filter, which is connected the said first detector. The subtraction unit is connected with the first detector and the second detector.

The present invention method can be also realized with a remote control device for sound-reproducing equipment comprising consecutively connected a sound sensor, an analysis and control unit, a command forming unit, and a transmitter. The analysis and control unit is operative to form on its output a first control signal upon detecting human voice features in the signal from the sound sensor and to form on its output a second control signal, when there are no human voice features in the signal from the sound sensor. The command forming unit is operative to form at least one remote control command for decreasing volume upon receiving on its input the first control signal and to form at least one remote control command for increasing volume upon receiving on its input the second control signal.

Further, the present invention remote control device comprises a reference signal receiver, connected with the analysis and control unit operative to detect voice features in the signal received from the sound sensor by the way of comparing the signal with a signal received from the reference signal receiver.

Further, the present invention remote control device comprises an additional sound sensor, connected with the analysis and control unit operative to detect human voice features in the signal received from the sound sensor by comparing the signal with the signal received from the additional sound sensor.

Upon detecting human voices and speech in particular within the monitored area, the volume of audio reproduction decreases to the low preset level, and in case of the absence of the human voices, the volume increases to the high preset level. The rules of changing the volume with time during its increase or decrease are determined according to the predetermined functions of time. This is achieved due to peculiarities of implementing the analysis and control unit in devices according to the present invention. The control of the presence of human voices and speech in particular within the monitored area is implemented by the way of detecting of corresponding features in the observed signal received from the sound sensor. The comparison of the observed signal from the sound sensor with the signal of the sound signal source or with the signal from the additional sound sensor is also used.

The method for the volume control of the audio reproduction is carried out in the following way.

During the audio reproduction, it is checked, if there are human voices within the monitored area Simultaneously, the volume is controlled according to the results of the check. The high and low volume levels are preset before the audio reproduction. If human voices are detected, the volume level is set to the low preset volume level. If no voices are detected, the volume level is set to the high preset volume level. The volume change from the high preset to the low preset level is implemented according to the first predetermined function of time, and the volume change from the low preset to the high preset level is implemented according to the second predetermined function of time.

The above first and/or second predetermined functions of time can comprise at least one time segment, during which the volume level does not change and following it another time segment, during which the volume level changes monotonically. During the monotonic increase of the volume level, in every following moment of time the volume is higher than in the previous one. Similarly, during the monotonic decrease of the volume level, the volume in every following moment of time is lower than in the previous one.

The above first and/or second predetermined functions of time can be formed depending on the characteristics of the detected human voice sounds. For example, the louder the voice detected in the monitored area, the faster the first predetermined time function can change, and consequently, the faster the volume level decreases upon the detection of this voice.

The control for the human voice presence can be switched by a conversion of sounds within the monitored area into an observed signal and checking the signal for the presence of human speech in it. For example, the level of spectrum components in the range of 200 . . . 1200 Hz corresponds to the range of main tones of human voices during the pronunciation of vowels. Human voices are considered detected, if the level of said spectrum components exceeds the set threshold.

The control for the human voice presence can be switched by the conversion of sounds within the monitored area into an observed signal, the conversion of sounds in another area into an additional observed signal and comparison of the observed signal to the additional observed signal.

When the observed signal is compared to the additional observed signal, it is possible to detect an envelope in each of said signals and to measure a level of the envelope components in the frequency range specific for the signals generated by human voices. For example, it can be the range of 2 . . . 8 Hz corresponding to phonemes frequencies. Further, the measuring results for both signals are compared and according to the comparison result, it is determined, if human voices are detected within the monitored area. Human voices are considered to be detected, if the part of said frequency components in the observed signals exceeds the part of said frequency components in the additional observed signal above the preset threshold value.

A more detailed disclosure of the present invention method is provided through the description of the volume control system and of the remote control devices implementing the claimed method.

### BRIEF DESCRIPTION OF THE DRAWINGS

Further the invention will be illustrated by the accompanying drawings.

FIG. 1 shows an overview of a system for volume control and an illustration of its use;

FIG. 2 shows the system structural scheme;

FIG. 3 shows a structural scheme of the first embodiment of an analysis and control unit;

FIG. 4 shows a structural scheme of the second embodiment of the analysis and control unit;

FIG. 5 shows a structural scheme of the third embodiment of the analysis and control unit;

FIG. 6 shows a flow-chart of an operation program of a microprocessor in the volume control system;

FIG. 7 shows a structural scheme of a remote control device;

FIG. 8 shows an outlook of the remote control device;

FIG. 9 shows a flow-chart of an operation program in the remote control device; and

FIG. 10 shows a variant of the remote control device use.

### THE PREFERRED EMBODIMENTS OF THE INVENTION

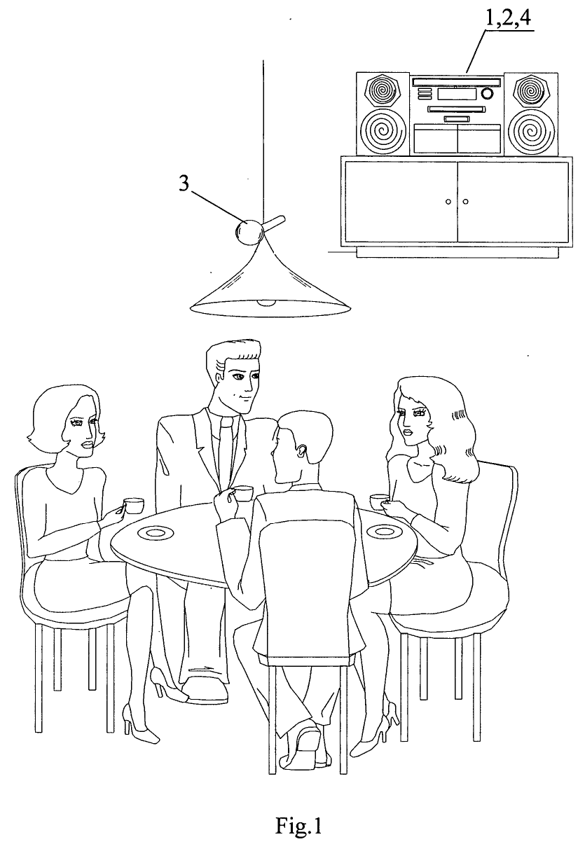

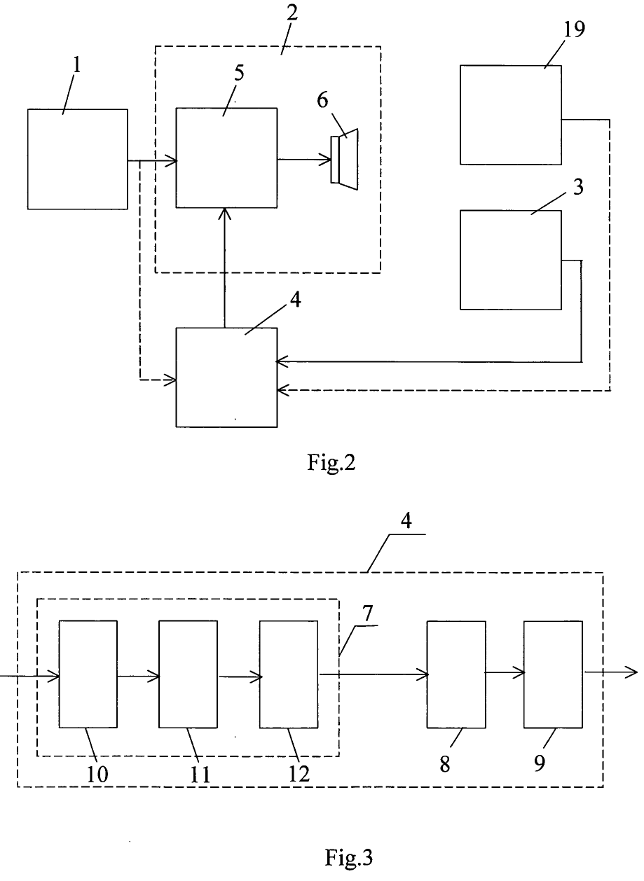

The volume control system comprises (FIG. 1 and FIG. 2) sound signal source 1, sound-reproducing unit 2, sound sensor 3, and analysis and control unit 4. The output of sound signal source 1 is connected to the input of sound-reproducing unit 2. The input of analysis and control unit 4 is connected to the output of sound sensor 3, and the output is connected to the volume control input of sound-reproducing unit 2. Analysis and control unit 4 is operative to detect human voice features in the signal received on its input and to form on its output a control signal depending on the result of detecting human voice features. Also, analysis and control unit 4 is operative to form on its output a control signal providing the volume decrease in sound-reproducing unit 2 in accordance to a first predetermined function of time to a low preset level upon the detection of human voice features and the volume increase in sound-reproducing unit 2 according to a second predetermined function of time to a high preset level, if human voice features are not detected.

Constructively, sound source signal 1, sound-reproducing unit 2, and analysis and control unit 4 can be implemented in a form of a music center. In this case, a radio-receiver, a compact disc or tape player can be sound signal source 1. It is also possible to implement sound signal source 1, sound-reproducing unit 2, and analysis and control unit 4 as a video complex including a TV set, a video tape or DVD player, etc.

Sound-reproducing unit 2 can comprise amplifier 5 and loudspeaker 6. Amplifier 5 can have a regular volume control with the help of a potentiometers, buttons or a remote control device and an additional volume control by the way of transmitting a control signal in a form of DC voltage to the volume control input. In this case, amplifier 5 must comprise at least one cascade, the amplifying of which is controlled by the control signal in the form of DC voltage received on amplifier 5. Sound-reproducing unit 2 can also comprise a microprocessor, which along with other functions also controls the volume. In this case, one of microprocessor inputs (input/output ports) can be a volume control input, and the control signal can have the form of a digital code.

All units of the device can get power from a regular AC power supply.

The volume control system can be both one-channel (monophonic) and multi-channel (stereophonic, quadrophonic, etc.). In the second case, the output of sound signal source 1, the input of sound-reproducing unit 2, and the second input of analysis and control unit 4 comprise several contacts, via each of which a signal of one of sound channels is received. Loudspeaker 6 can consist of several loudspeakers corresponding to the number of sound channels.

Sound sensor 3 can be implemented in a form of a microphone connected to the amplifier, which is constructively located in analysis and control unit 4.

Sound sensor 3 can be operative to control sound level within a set area of space. This can be provided by the form of sound sensor 3 pattern and/or sound sensor 3 location in the monitored area.

Analysis and control unit 4 can be constructively located in a separate housing, displaced in a certain distance from sound-reproducing unit 2. The output of analysis and control unit 4 can be connected to the volume control input of sound-reproducing unit 2 by the means of a wire, or the connection can be wireless by infra-red rays, radio waves, ultrasound, etc. For example, the housing of analysis and control unit 4 can be the housing of a remote control device of sound-reproducing unit 2. Sound sensor 3 can also be displaced inside this remote control device. In this embodiment, analysis and control unit 4 can receive power from batteries or an accumulator. It is possible to receive power from AC power source via a transformer, rectifier, and a stabilizer.

Analysis and control unit 4 (its first embodiment) can comprise (FIG. 3) consecutively connected feature detection unit 7, measuring unit 8, and control signal former 9, the output of which is the output of analysis and control unit 4, the input of which is the input of feature detection unit 7.

Feature detection unit 7 can comprise consecutively connected band-pass filter 10, detector 11 and low-pass filter 12, the output of which is the output of feature detection unit 7, the input of which is the input of band-pass filter 10.

Band-pass filter 10 selects a frequency band typical for sound vibration during the pronunciation of vowels by a human voice, for example 200-1200 Hz. Detector 11 selects a root-mean square or half-period average voltage of the signal. Low-pass filter 12 smoothes the flicker and provides a required time constant of the voltage change at the output of feature detection unit 7. In the described case, the detected feature will be root-mean square or half-period average value of the signal measured in the frequency band selected by band-pass filter 10.

Measuring unit 8 can be embodied in a form of analog-to-digital converter (ADC), at the input of which there is an amplifier with controlled voltage offset and amplification coefficient. Control signal former 9 can comprise a microprocessor, one of the input/output ports of which is the input of former 9, and to the other input/output ports are consecutively connected a digit-to-analog converter (DAC), and DC amplifier (DCA), the output of which is the output of former 9. DCA can have regulators for the initial level offset and amplification.

Microcontroller can be PIC16F83 by Microchip, USA. The flow-chart of the program run by the microprocessor will be described further.

Functions of former 9 can be also fulfilled by the microprocessor controlling the operation of sound-reproducing unit 2 and sound signal source 1. In this case, one of the microprocessor inputs can be connected to the output of measuring unit 8. It is also possible to implement analysis and control unit 4 as a whole on the basis of a digital signal processor (DSP) or a microprocessor. In this case, functions of all units that make up analysis and control unit 4 are done by program means. This variant especially convenient in case of using the sound signal source with a digital output is not described here.

Analysis and control unit 4 can be equipped by a reference signal input connected to the output of sound signal source 1 (FIG. 2) and operative to detect human voice features in the signal received on its input by the way of comparing said signal to the signal received on its reference input.

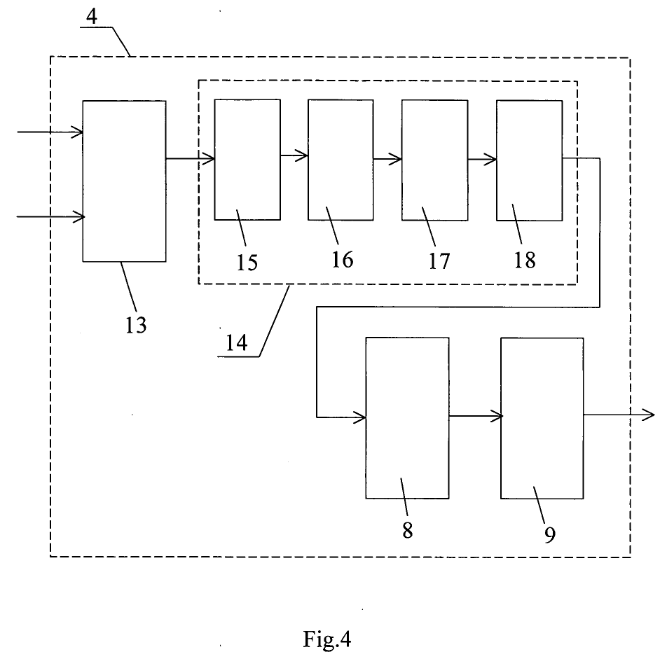

In this case, analysis and control unit 4 (its second embodiment) can comprise (FIG. 4) consecutively connected subtraction unit 13, feature detection unit 14, measuring unit 8, and control signal former 9, the output of which is the output of analysis and control unit 4, the first and second inputs of which are the first and second inputs of subtraction unit 13, accordingly.

Subtraction unit 13 can comprise an analog subtractor, in which the signal received on the second input of subtraction unit 13 is subtracted from the signal received on its first input Subtraction unit 13 can be equipped by means of adjusting of transmission coefficients according to its first and second inputs.

In case of a stereophonic sound-reproducing device, subtraction unit 13 can comprise an adder, which forms a sum of weighted sound channels signals received on the second input of said unit 13.

Subtraction unit 13 can be implemented as in the device according to U.S. Pat. No. 5,615,270, 1997, and comprise adaptive digital filters. Sound channel signals from the second input are put through these filters and then are subtracted from the signal at the first output of said unit. In this case, subtraction unit 13 can be implemented on DSP, in which all signal operations are done in a digital format. ADCs must be connected to the two inputs of DSP that form the first and second inputs subtraction unit 13. DAC must be connected to the output of DSP that forms the output of subtraction unit 13. If signals from sound signal source 1 are received in the digital form, the ADC on the second input of subtraction unit 13 is not required. The use of adaptive filters provides automatic adjusting of transmission coefficients for sound channels signals and taking into account the reflection of sound waves generated by loudspeaker 6 from the walls and various objects, before these sound waves reach sound sensor 3.

Feature detection unit 14 can comprise consecutively connected (FIG. 4) envelop detector 15, band-pass filter 16, detector 17, and low-pass filter 18. The output of low-pass filter 18 is the output of feature detection unit 14, the input of which is the input of envelope detector 15. Band-pass filter 16 can have a band pass in the range of 2 . . . 8 Hz corresponding to the frequency range of phonemes in human speech. Detector 17 selects a root-mean square or half-period average voltage of a signal received on its input.

In the described embodiment, the voltage is formed at the output of feature detection unit 14. The voltage shows the level of frequency component falling within the frequency range of phonemes in the signal envelope at the input of said unit. It is possible that unit 14 detects other features. For example, it is possible to measure the sound signal energy within the preset frequency range and the value of said energy variation in time as in the device according to U.S. Pat. No. 5,826,230, 1998.

Measuring unit 8 and former 9 are the same as described before.

The volume control system can be equipped by additional sound sensor 19, the output of which is connected to the additional input of analysis and control unit 4 (FIG. 2), which can be operative to detect human voice features in the signal received on its input by the way of comparing this signal with the signal received on its additional input.

Additional sound sensor 19 can comprise a microphone and an amplifier. The amplifier can be connected to analysis and control unit 4. Sound sensor 3 can be operative to control the sound level within a certain area. Additional sound sensor 19 can be operative to control sound level generated by sound-reproducing unit 2. Said features of sound sensor 3 and additional sound sensor 19 can be provided by the corresponding location of these sensors in space and by a corresponding polar pattern.

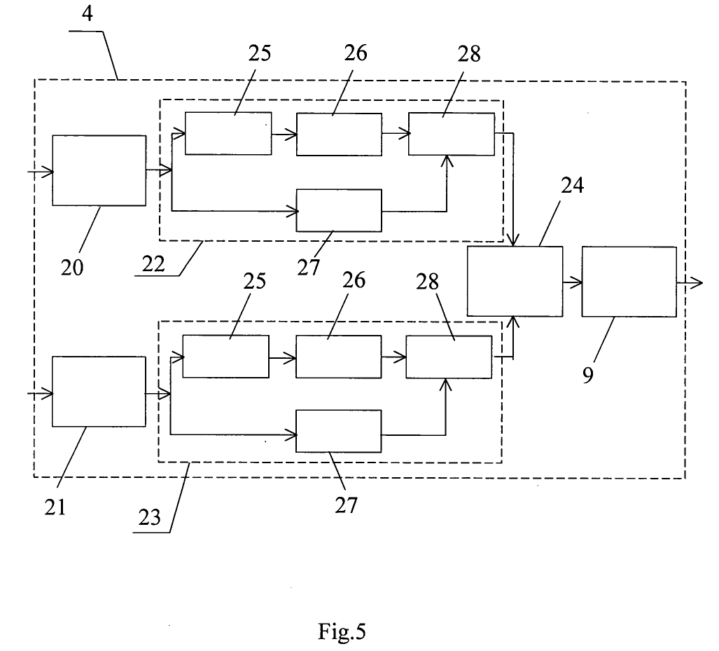

In the embodiment with additional sound sensor 19, analysis and control unit 4 (the third variant of its embodiment) can comprise (FIG. 5) first and second detectors 20 and 21, first and second measuring units 22 and 23, comparison unit 24, and control signal former 9. The inputs of first and second detectors 20 and 21 are first and second inputs of analysis and control unit 4, accordingly, and their outputs are connected to the inputs of first and second measuring units 22 and 23, accordingly, the outputs of which are connected to the first and second inputs of comparison unit 24, accordingly, the output of which is connected to the input of control signal former 9, the output of which is the output of analysis and control unit 4.

Detectors 20 and 21 can be regular amplitude detectors providing the detection of the signal envelope. Comparison unit 24 can comprise an analog subtractor, the inputs of which are the inputs of comparison unit 24, and the output is connected to the input of the ADC, the output of which is the output of comparison unit 24. Control signal former 9 is the same as in the embodiment of analysis and control unit 4 shown in FIG. 3.

First measuring unit 22 can comprise a band-pass filter 25, first and second detectors 26 and 27, and division unit 28, the output of which is the output of first measuring unit 22, the input of which is connected to the inputs of second detector 27 and band-pass filter 25, the output of which via first detector 26 is connected to the first input of division unit 28, the second input of which is connected to the output of second detector 27.

Second measuring unit 23 is implemented as first measuring unit 22.

Band-pass filter 25 selects a frequency band corresponding to the frequency range of phonemes in human speech, usually 2 . . . 8 Hz. Detectors 26 and 27 can be implemented in a form of detectors of root-mean square or half-period average AC voltage. Division unit 28 fulfils the operation of dividing the voltage value on its first input on the voltage value on its second input.

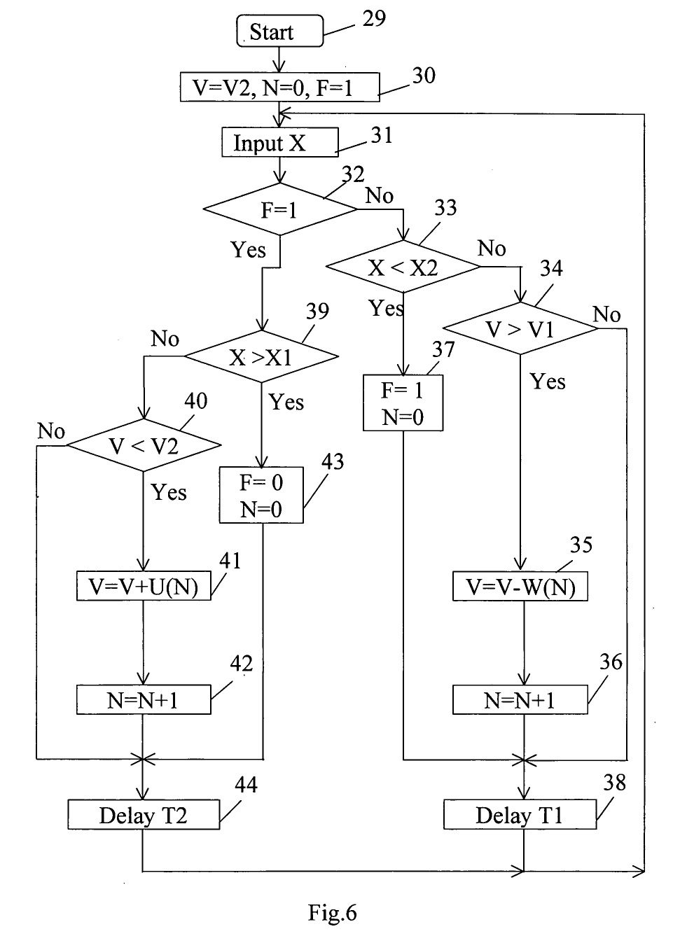

The flow-chart of the program fulfilled by microprocessor in control signal former 9 (FIG. 6) comprises program blocks 29 . . . 44.

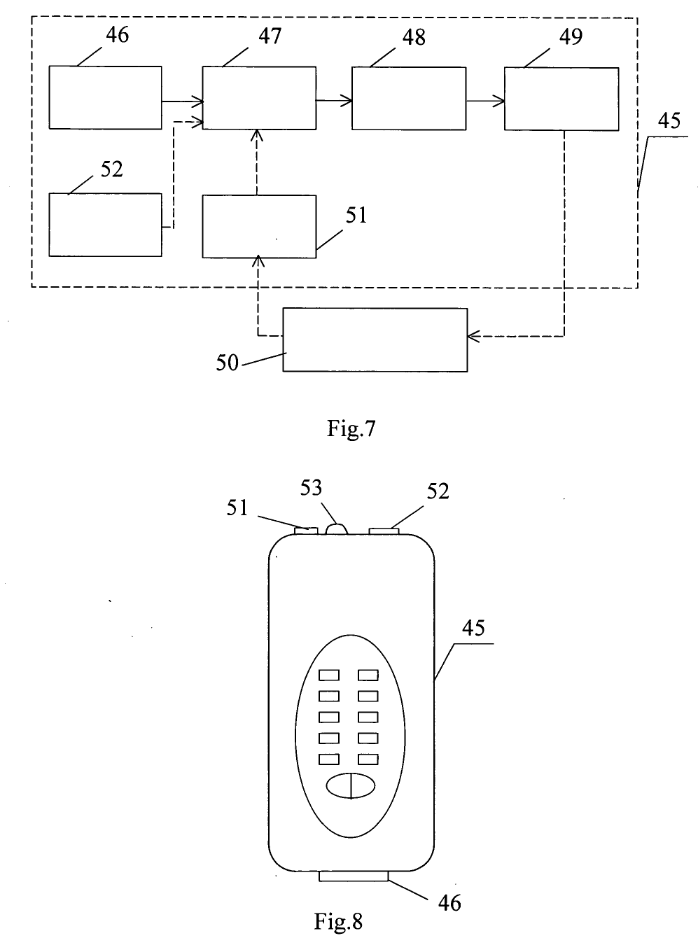

Remote control device 45 for sound-reproducing equipment (FIG. 7) comprises consecutively connected sound sensor 46, analysis and control unit 47, command forming unit 48, and transmitter 49. FIG. 7 also shows controlled device 50 controlled with remote control device 45. Controlled device 50 can be a music center, a TV set, etc. Transmitter 49 is connected to controlled device 50 with the help of IR-rays, or radio waves, or wires, or any other known means.

Analysis and control unit 47 is operative to form on its output a first control signal upon the detection of human voice features in the signal from sound sensor 46 and to form on its output a second control signal, if there are no human voice features in the signal received from sound sensor 46. Command forming unit 48 is operative to form at least one command of volume decrease upon appearing on its input of the first control signal and to form at least one command of volume increase upon appearing on its input of the second control signal.

Analysis and control unit 47 can be implemented similar to analysis and control unit 4 shown in FIG. 3. The difference lies in the program run by microprocessor in control signal former 9 which will be further considered.

Controlled device 50 can have some standard remote control commands set and a standard transmission protocol for remote control commands. For example, controlled device 50 can meet RC-5 standard.

Remote control device 45 can be equipped by reference signal receiver 51, the output of which is connected to the input of the reference signal of analysis and control unit 47, which in this case can be operative to detect human voice features in the signal received on its input by the way of comparing said signal with the signal received on the reference signal input.

In this case, analysis and control unit 47 can be implemented similar to the second embodiment of analysis and control unit 4 (FIG. 4). The difference lies in the program run by microprocessor in control signal former 9 that will be further considered.

Reference signal receiver 51 can receive sound signals transmitted from controlled device 50. These signals can be received for example from a headphone connector, that any electronic device able to reproduce sound has. In this case, reference signal receiver 51 can comprise a connector for connecting cable and input amplifiers. It is possible to use a wireless connection between controlled device 50 and reference signal receiver 51, for example with the use of IR-rays, radio waves, and other known means.

Remote control device 45 can be equipped by an additional sound sensor 52, the output of which is connected to the additional input of analysis and control unit 47, which in this case can be operative to detect human voice features in the signal received on its input by the way of comparing said signal to the signal received on its additional input.

In this case, analysis and control unit 47 can be implemented similar to the third embodiment of analysis and control unit 4 (FIG. 5). The difference can lie in the program run by microprocessor in control signal former 9 that will be considered further.

Constructively, remote control device 45 can be implemented as a regular remote control device (FIG. 8). Sound sensor 46 can be displaced on the side of the housing of the remote control device opposite to the side, on which light-emitting diode (LED) 53 is mounted. LED 53 is a part of transmitter 49. Additional sound sensor 52, if there is any in the device, can be mounted near LED 53. Reference signal receiver 51 can be displaced on any suitable place on the housing of remote control device 45, for example, near LED 53. Other constructive variant of remote control device 45 are also possible.

Remote control device 45 can receive power from batteries as in regular remote control devices. It is also possible to receive power from AC power source, for example via a standard power connector.

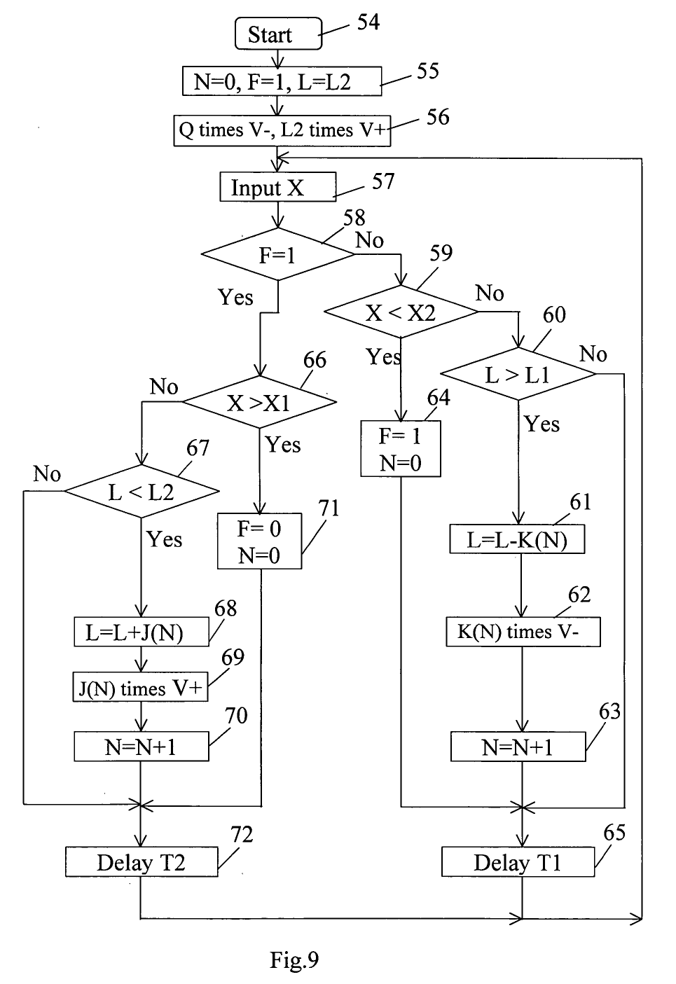

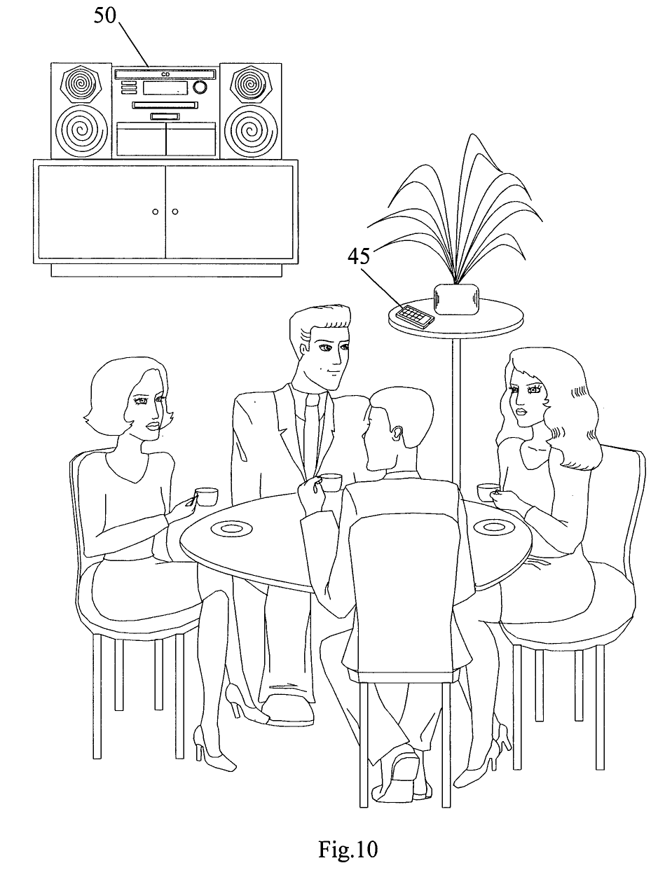

Commands forming unit 48 can comprise a microprocessor and a keyboard as in standard remote control devices. The same microprocessor can fulfil the functions of control signal former 9 in analysis and control unit 47. The flow-chart of the microprocessor operation for this case comprises program blocks 54 . . . 72 (FIG. 9).

It is possible to use a separate microprocessors for fulfilling the functions of command forming unit 48 and analysis and control unit 47. Programs for this variant are not considered here.

It is possible to implement remote control device 45 without a keyboard. In this case, device 45 fulfils only the function of the automatic volume control according to the present invention.

During its operation, remote control device 45 is displaced between a certain area, where people are present, and controlled device 50 (FIG. 10). Sound sensor 46 has to be directed to the monitored area, and LED 53—to controlled device 50.

### OPERATION OF THE VOLUME CONTROL SYSTEM

Sound signal source 1 (FIG. 2 and FIG. 3) forms a sound signal, for example by playing a compact disc. This signal is received by sound-reproducing unit 2, where it is amplified in amplifier 5 and converted into sound in loudspeaker 6.

After the device is switched on, the control signal level at the output of analysis and control unit 4 is automatically set to insure the high preset volume level that provides comfortable conditions for listening to music.

Sound sensor 3 perceives sounds generated in a certain monitored area, where people are located. It can also perceive sounds generated by sound-reproducing unit 2. In the result, at the output of sound sensor 3 an observed signal is formed comprising components corresponding to the sounds generated by sound-reproducing unit 2 and components corresponding to sounds generated by other sources including human voices in the monitored area.

The observed signal from sound sensor 3 is received on the input of analysis and control unit 4, wherein it is checked, if this signal comprises human voice features, for example, typical frequency components generated by human speech in the monitored area. Said frequency components usually fall in the range of 200 . . . 1200 Hz.

If human voice features are detected, analysis and control unit 4 generates a control signal received on sound-reproducing unit 2 and causing the volume decrease to the low preset level. Due to this, sounds generated by sound-reproducing unit 2 do not impede people's conversation within the monitored area. If human voice features are not detected in the observed signal from sound sensor 3, the volume is maintained at the previously set low preset level.

After human voices are detected within the monitored area and the volume is decreased to the low preset level, analysis and control unit 4 continues to check for the above-described components in the observed signal from sound sensor 3, that is to check for the presence of human voices in the monitored area After people terminate the conversation, voice features disappear in the observed signal from sound sensor 3, and analysis and control unit 4 generates a control signal that causes the volume increase in sound-reproducing unit 2 to the high preset level. As a result, optimal conditions for listening to music are retained.

The volume decrease and increase is carried out according to a first and second predetermined functions of time, accordingly, that is why the change from the low preset level to the high preset level proceeds smoothly during the corresponding periods of time. Lengths of these periods for increasing and decreasing volume can be different. For example, the volume decrease upon detection of speech can be done quickly, while the increase of volume after the termination of the conversation can proceed rather slowly. Before the beginning of the volume decrease and/or increase, pauses of set lengths can be made.

For the purpose of detecting human voice features and speech in particular, band-pass filter 10 in feature detection unit 7 (FIG. 3) selects a frequency band typical for sound vibrations during the pronunciation of vowels by people, usually 200 . . . 1200 Hz. Detector 11 selects a root-mean square value of signal voltage for the signal that passed through band-pass filter 10, and low-pass filter 12 smoothes the output voltage of detector 11. In measuring unit 8, the voltage from the output of feature detection unit 7 is amplified, offset, and converted into a digital form.

The operation of control signal former 9 is explained with the help of the flow-chart of the program (FIG. 6) run by the microprocessor used in said unit. The control signal voltage is formed by the way of outputting the code of variable V via the microprocessor input/output port and converting said code into the voltage with DAC and amplifier. The control signal voltage levels, which provide the receiving of high and low preset volume level, are achieved, when codes of numbers V1 and V2 are input, accordingly. In the program flow-chart, the following variables are also used: variable X showing the value of the signal on the input of former 9; logical variable F showing the direction of the volume change (F=1 corresponds to the volume increase, F=0 corresponds to the volume decrease); whole-number variable N used as a counter; and number arrays U(N) and W(N), wherein N=1 . . . M, M is a set whole number. These arrays are used to set functions of time according to which the volume is increased or decreased, accordingly. Variables X1 and X2 are used to set high and low threshold values of variable X, accordingly.

The running of the program begins after the system is switched on (block 29). Variable V receives value V2 and a corresponding code is output via the microprocessor input/output port. In the result, the high preset volume level is set (block 30). Variable N receives the value of 0, and variable F—the value of 1. After this, the program continues to the loop consisting of program blocks 31 . . . 44, which continues till the system is switched off.

At the beginning of each run of the loop, variable X receives the value of the number input by microprocessor via input/output port. Said ports fulfill the functions of the input of control signal former 9 (block 31). Consequently, the value of variable X reflects a quantitative measure of the presence of human voices in the signal from sound sensor 3.

In program block 32, the current value of variable F is checked. If F=0, then in program block 33 the value of variable X is compared to the low threshold value X2. If X<X2, Variable F receives the value of 1, variable N—the value of 0 (block 37). That is how the switch of the volume change direction to the increase is established, when no human voice features are detected in the observed signal. After this, delay T1 is formed (block 38). Then the program returns to the beginning of the loop in block 31.

If a negative answer is received in block 33, it is checked if V>V1 (block 34), that will determine the termination of the volume decrease process. If V>V1, variable V decreases by value W(N) (block 35), and a new value of variable V via the microprocessor input/output port is received at the output of control signal former 9. After this, the value of counting variable N increases by 1 (block 36). Further, the program continues to block 38 described before.

If in program block 34 a negative answer is received, the further decrease of variable N, and consequently the decrease of volume, is not made, as the low preset level is already reached. In this case, the program continues directly to program block 38.

If in program block 32, it is found that F=1, in program block 39 the value of variable X is compared to the high threshold value X1. If X>X1, variables F and N receive the values of 0 (block 43). In this way the volume change direction is switched over to the volume decrease, when human voice features are detected in the observed signal. Further, delay T2 is formed (block 44), after which the program returns to the beginning of the loop in program block 31.

If a negative answer is received in program block 39, it is checked if V<V2 (block 40), that determines the termination of the volume increase process. If V<V2, variable V increases by value U(N) (block 41), and a new value of variable V via the microprocessor input/output port is received at the output of control signal former 9. After this, the value of counting variable N increases by 1 (block 42). Further, the program continues to block 44, which was described before.

If in program block 40 a negative answer is received, the further increase of variable V, and consequently the further volume increase is not made, as the high preset level is already reached. In this case, the program continues directly to program block 44.

The program described provides the volume increase, if the value of variable X is lower than the low threshold X2. Values U(N) of variable V increments are prerecorded in the memory of the microprocessor, that fulfils the functions of control signal former 9. Thanks to this, the function of time is determined, according to which the volume increase is made. For example, several first values of array U(N) can be equal to zero providing a delay before the volume begins to increase. Then, the volume can monotonically increase in time linearly or nonlinearly depending on preset values U(N). Variable N receives the value of 0 every time the direction of the volume change is switched over. By changing the time of delay T2, it is possible to increase or decrease the total length of the volume change process from the first preset value to the second preset value.

Similarly, the volume decrease is carried out, if the value of variable X is higher than the high threshold X1. The type of the time function, in accordance with which the volume is decreased, is determined by array of number W(N), determining the negative increments of variable V for each loop run, after the volume has begun to increase. The speed of the volume decrease is determined by the time of delay T1, which can be made dependent on variable X. For example, if X<X1, delay T1 can be the longest. The more X exceeds X1, the shorter becomes delay T1. The necessary dependence can be implemented with the help of a table recorded in the memory of the microprocessor. Due to this, louder voice sounds in the monitored area cause a faster volume decrease, than voice sounds slightly exceeding the threshold of their detection.

The presence of two threshold values X1 and X2 create a hysteresis providing a stable operation of the system, when sound sensor 3 partially perceives sounds generated by sound-reproducing unit 2. Besides, for a stable operation of the system, it is necessary that the value of variable X is below the low threshold X2, when there are no human voices in the monitored area and when the high volume level is established. This condition can be fulfilled simultaneously with fulfilling the main system function, if the sensitivity of sound sensor 3 to sounds generated in the monitored area sufficiently exceeds its sensitivity to sounds generated by sound-reproducing unit 2.

Another possible way of providing the stability of the system is to implement feature detection unit 7 operative to detect in the observed signal from sound sensor 3 a feature (features), the value of which is sufficiently different for human voices and other sounds, for example for music. The example of devices that can be used for this purpose are disclosed in U.S. Pat. Nos. 5,372,392, 1998, 5,826,230, 1998, and others.

Beside the program described, other embodiments of volume control depending on the presence of sounds within the monitored area can be employed. For example, the volume can increase, when the level of surrounding noise increases. The corresponding programs are not considered here, as other variants of volume control are beyond the scope of the present invention.

Further we will proceed considering the case, when there is a connection between the output of sound source signal 1 and the input of the reference signal of analysis and control unit 4 according to the second embodiment (FIG. 4). In this case, in analysis and control unit 4 signals on its input and output are compared. In the result, it is determined, if in the signal from sound sensor 3 there are components comprising human voice features not present in the reference signal from the sound signal source 1. In this way, the checking for the presence of human voices within the monitored area is carried out. The rules of volume change in sound-reproducing unit 2 upon the detection of human voice and upon their absence can be the same as described for the first embodiment of analysis and control unit 4.

In the considered embodiment, in subtraction unit 13 (FIG. 4) a difference signal is formed by the way of subtracting of the reference signal generated by sound source signal 3 received on the second input of said unit from the observed signal of sound sensor 3 received on its first input. If subtraction unit 13 comprises a regular analog subtractor, transmission coefficients for both inputs should be adjusted manually before the operation of the system to provide a complete suppression of the components generated by sound signal source 1 in the difference signal. Such adjustment should be repeated each time the location of loudspeaker 6 relative to sound sensor 3 is changed.

If subtraction unit 13 comprises adaptive filters, then these filters are automatically adjusted. This provides the complete coinciding of said components in the difference signal.

Thus, the difference signal at the output of subtraction unit 13 does not comprise components generated by the sounds of sound-reproducing unit 2 and comprises only components generated by other sound sources, including human voices within the area monitored by sound sensor 3. Further, the difference signal is checked for the presence of human voice features.

The difference signal from the output of subtraction unit 13 is received at feature detection unit 14. In the embodiment being described, detector 15 in this unit selects AC voltage of the signal envelope, and band-pass filter 16 selects from the signal envelope a frequency band 2 . . . 8 Hz corresponding to phonemes frequency in human speech. Then, rectifier 17 and low-pass filter 18 convert the received signal into DC voltage, the level of which shows the presence of the selected feature, and more precisely, the presence of the changes in the sound signal envelope with frequencies characteristic of human speech.

Measuring unit 8 and control signal former 9 can operate as it was described before, including the program run by microprocessor in control signal former 9.

Further, we will proceed considering a device comprising additional sound sensor 19, the output of which is connected to the additional input of analysis and control unit 4 implemented as in the third embodiment (FIG. 5).

In this variant, sound sensor 3 predominantly perceives sounds generated in the monitored area and additional sound sensor 19 predominantly perceives sounds generated by sound-reproducing unit 2. The observed signal from sound sensor 3 and an additional observed signal from additional sound sensor 19 are received correspondingly at the input and the additional input of analysis and control unit 4, wherein the two signals are compared with the set parameters. According to the comparison results, it is determined if human voices and speech in particular are detected within the monitored area. The rules for volume change upon detecting human voices or in case of their absence can be the same as described for the first embodiment of analysis and control unit 4.

In analysis and control unit 4, each of detectors 20 and 21 selects AC voltage of the signal envelope received on its input. In measuring unit 22, band-pass filter 25 selects from envelope the preset frequency range of 2 . . . 8 Hz, wherein frequencies of phonemes in human speech fall. Each of detectors 26 and 27 selects a root-mean square value of the voltage on its input and averages this value for the preset period of time. In division unit 28, the voltage received from detector 26 is divided by the voltage received from detector 27. In the result, at the output of measuring unit 22, the voltage is formed proportionally to the ratio of the energy of the input signal within the 2 . . . 8 Hz frequency band to the total energy of this signal. The voltage shows the part of the energy of frequency components within the preset frequency range, and consequently generated with high probability by human speech, in the total energy of the signal received from sound sensor 3.

Measuring unit 23 operates in the same way. At its output the voltage is formed, the value of which shows the part of the energy of frequency components with big probability generated by human voices in the total energy of the signal received from additional sound sensor 19. In comparison unit 24, the difference between the voltage on the outputs of first and second measuring units 22 and 23 is found. Then, this difference is converted into the digital form. Further, said difference is received at the input of control signal former 9, which operates as in the earlier described embodiments, including the program run by the microprocessor used in this unit

### OPERATION OF THE REMOTE CONTROL DEVICE FOR SOUND-REPRODUCING EQUIPMENT

Remote control device 45 for sound-reproducing equipment is displaced between the monitored area, wherein people are located, and controlled device 50 (FIG. 10). Sound sensor 46 has to be directed to the monitored area, and LED 53—to controlled device 50. The volume is controlled by the way of forming and sending remote control commands from remote control device 45 to controlled device 50. Besides the volume control depending on detecting human voices within the monitored area, remote control device 45 can form and transmit other commands, for example of switching on/off the sound reproduction, rewinding, etc.

After switching remote control device 45 (it is assumed that controlled device was switched on before), analysis and control unit 47 and commands forming unit 48 automatically form the sequence of remote control commands. In the result of transmitting these commands to controlled device 50, the high preset volume level is established providing comfortable conditions for listening to music.

During its further operation, in remote control device 45 the observed signal from sound sensor 46 is received at the input of analysis and control unit 47, which generates control signals arriving at commands forming unit 48, which forms codes of corresponding remote control commands in a form of voltage pulse sequences in accordance with a used commands transmission protocol. Further, these voltage pulses are received at transmitter 49, wherein with the help of LED 53 they are converted into IR pulses transmitted to controlled device 50.

If human voice features are detected in the observed signal received from sound sensor 46, analysis and control unit 47 forms control signals received at commands forming unit 48, which forms the sequence of remote control commands causing the volume decrease to the low preset level. If human voice features are not detected in the observed signal from sound sensor 46, the volume is maintained at the earlier set high preset level.

After people terminate the conversation, human speech features in the observed signal from sound sensor 46 disappear, and analysis and control unit 47 generates control signals received at commands forming unit 48, which forms a sequence of remote control commands causing the volume increase to the high preset level. In the result, the optimal conditions for listening to music are retained.

The volume increase and decrease can be made in accordance to the first and second functions of time, the peculiarities of which are the same as for the earlier described sound-reproducing device according to the present invention.

Analysis and control unit 47 in remote control device 45 mainly operates as earlier described analysis and control unit 4 (FIGS. 2, 3). The difference lies in the program. FIG. 7 shows its flow-chart for the case when the same microprocessor is used to fulfil the functions of control signal former in analysis and control unit 47 and the functions of commands forming unit 48.

The volume is controlled by the way of sending volume increase commands (in the flow-chart indicated as V+) and volume decrease commands (indicated as V−) from remote control device 45 to controlled device 50. The volume in controlled device 50 changes discretely and can possesses Q values (for example, Q=64). Each volume increase command causes the transition to the next higher volume level. Each volume decrease command causes the transition to the next lower volume level.

The whole number showing the current discrete volume level is stored in variable L. The values of L corresponding to the high and low preset volume levels are designated L1 and L2, accordingly. In the flow-chart of the program the following variables are used: variable X showing the signal value at the input of control signal former 9; logical variable F showing the direction of the volume change (F=1 for the increase, F=0 for the decrease), whole-number variable N used as a counter; and number arrays of whole numbers J(N) and K(N), where N=1 . . . M, M is a set whole number. With the use of these arrays, functions of time are predetermined, with the help of which the volume is increased and decreased, accordingly. With the help of constants X1 and X2, high and low threshold values of variable X are set, accordingly.

The run of the program begins after remote control device 45 is switched on (block 54). Variable N receives the value of 0, variable F—the value of 1, and variable L—the value of L2 (block 55). Further, the sequence of remote control commands is formed, which provides the set of the high volume level (block 56). For this purpose, first for example the command of the volume decrease is formed Q times, and in the result the preset lowest volume level corresponding to L=0 is established. After this, the command of the volume increase is formed L2 times, and in result the volume level corresponding to the level of L=L2 is set After this, the program enters the loop consisting of program blocks 57 . . . 72, which continues till remote control device 45 is switched off.

In the beginning of each run of the loop, variable X receives the value of the number input by the microprocessor via input/output port, fulfilling the function of the input of control signal former 9 (block 57). As a result, variable X reflects the quantitative measure of human voice features presence in the observed signal from sound sensor 46.

In program block 58, the current value of variable F is checked. If F=0, then in program block 59 the value of variable X is compared to the low threshold value X2. If X<X2, variable F receives the value of 1, and variable N—the value of 0 (block 64). In this way the direction of the volume change is switched over to the increase, when human voice features are not detected in the observed signal. Further, delay T1 is formed (block 65), after which the program returns to the beginning of the loop in program block 57.

If in program block 59 a negative answer is received, it is checked if L>L1 (block 60) to determine if the volume decrease process has terminated. If L>L, variable L decreases by K(N) (block 61) and the volume decrease command is formed and transmitted K(N) times (block 62). The value of counting variable N increases by 1 (block 63). Further, the program continues to block 65 described above.

If in program block 60 a negative answer is received, then the further decrease of variable L, and consequently the volume decrease, does not take place as the low preset volume level is already reached. In this case, the program goes directly to program block 65.

If in program block 58 it is found out that F=1, then in program block 66 the value of variable X is compared to the high threshold value X1. If X>X1, variables F and N receive the value of 0 (block 71). In this way the volume change direction is switched over to the volume decrease, when human voice features are detected in the observed signal. Further, delay T2 is formed (block 72), after which the program returns to the beginning of the loop in program block 57.

If in program block 66 a negative answer is received, it is checked if L<L2 (block 67) to determine the termination of the volume increase process. If L<L2, variable L increases by J(N) (block 68) and the program of volume increase is formed and transmitted J(N) times (block 69). Then the value of counting variable N increases by 1 (block 70). Further, the program continues to block 72 described earlier.

If in program block 67 a negative answer is received, the further increase of variable L, and consequently the volume increase, is not made, as the high preset volume level is already reached. In this case, the program continues directly to program block 72.

The peculiarities of setting the functions of time, in accordance to which the volume is increased or decreased, of controlling the speed of volume change depending on value X by changing lengths of T1 and T2, of providing a stable operation due to hysteresis are the same as in the earlier described sound-reproducing device (FIG. 6 and the corresponding text).

Beside this program, the microprocessor can run other programs that provide forming and transmitting of various remote control commands upon activating of keys on a regular keyboard of remote control device 45. These programs as well as the subroutines of forming volume increase and decrease commands are not described here as they can be the same as the programs in the mass produced remote control devices. The program of automatic volume control considered above can be called as one of operation modes in remote control device 45.

The described program can be also used, when in analysis and control unit 47 there is a separate microprocessor, and commands forming unit 48 is a standard integrated circuit (IC) for the remote control device connected to the keyboard. In this case, when operations of sending volume increase (V+) and volume decrease (V−) commands are fulfilled, the electronic switches can be used. Said switches are controlled by the microprocessor in analysis and control unit 47 and attached parallel to the contacts or keyboard buttons, the pressing of which initiates forming and sending of said commands in a regular operation mode.

In this variant, to form volume decrease commands upon the detection of human voice features in the monitored area (blocks 56 and 62) the microprocessor in analysis and control unit 47 forms a first control signal, according to which the contacts of volume decrease switch on the remote control device 45 lock. Under the influence of said control signal, commands forming unit 48 forms a standard volume decrease command transmitted to controlled device 50.

Similarly, to form volume increase commands when no human voice features are detected within the monitored area, the microprocessor in analysis and control unit 47 forms a second control signal, according to which the contacts of the volume increase switch lock. Under the influence of said control signal, commands forming unit 48 forms a standard volume increase command transmitted to controlled device 50.

Further we will consider the operation of remote control device 45, in case when it comprises reference signal receiver 51. In this case, analysis and control unit 47 is implemented as in FIG. 4 (the second embodiment), and its reference signal input is connected to the output of reference signal receiver 51. The sound signal from controlled device 50 via reference signal receiver 51 is received on the reference signal input in analysis and control unit 47, which operates mainly similar to the second embodiment of analysis and control unit 4 in the sound-reproducing device according to the present invention (FIG. 4 and the corresponding text). The difference lies only in the program run by the microprocessor (FIG. 9 and the corresponding text).

Finally, we will consider the case, when the device comprises additional sound sensor 52. In this case, analysis and control unit 47 operates mainly similar to the third embodiment of analysis and control unit 4 in the device according to the present invention (FIG. 5 and the corresponding text).The program run by the microprocessor is similar to the program shown in FIG. 9 described above.

### CONCLUSION, RAMIFICATIONS AND SCOPE

As it is clear from the description of the present invention, the invention provides the audio reproduction volume decrease to the low preset level upon detecting human voices within the monitored area, and the volume increase up to the high preset level, when there are no human voices in the monitored area. The volume is decreased and increased according to predetermined functions of time.

The use of the present invention method and the devices for carrying out said method provides a comfortable music background for conducting meetings, receptions and other events, and also inside a car. If gathered people conduct a conversation, the volume of the audio reproduction decreases to the level that does not impede the conversation and creates a favorable music background. When the conversation is over, the volume slowly increases filling the gap in the conversation and providing optimal conditions for listening to music.

The devices according to the present invention make it possible to set functions of time, in accordance to which the volume changes, and form these functions depending on human voices parameters. Due to this, the possibility is provided to choose optimal rules for volume change in audio reproduction for different uses. Thus, the possibilities of receiving a most convenient and probably a most effective sound surrounding are provided.

Along with carrying out the present invention method, said devices can fulfil other volume control variants depending on other sounds.

### IDUSTRIAL APPLICABILITY

The system according to the present invention can be used in living houses, in reception rooms, lobbies, inside cars, etc, for creating a comfortable atmosphere. In restaurants, cafes, clubs, it is possible to use at the same time several groups of the devices according to the present invention. Each system can be used to generate sound within an area comprising one or several tables and control the presence of human voices in said area creating for the people in the area most favorable sound surrounding. Similarly, the sound reproduction can be organized inside airplanes, automobiles, train cars, and other transportation means.

Another possible area of using the devices according to the present invention is in dance and aerobic classes, etc. In this case, the volume of music reproduction can be decreased, when a trainer or an instructor begins to speak. After he or she stops to give the commands, the music volume increases to the optimal for the class level.

The remote control devices according to the present invention can be used by individual users to control volume in a living or dining room. These devices easily comply with regular sound-reproducing equipment and can be operative to select a commands system out of several prerecorded systems or to teach the remote control device of a certain commands system.

The above advantages create good perspective for including the system according to the present invention into existing sound-reproducing devices.

Having described the preferred embodiments of the invention with the reference to the accompanying drawings, it is to be understood that the invention is not limited to this precise embodiment, and that various changes and modifications may be effective therein by one skilled in the art without departing from the scope or spirit of the invention as defined in the appended claims.

We claim:

1. A method of volume control comprising:
defining of a high preset volume level and a low preset volume level;
checking for a human voice presence in a monitored area during an audio reproduction; and
controlling of the volume of said audio reproduction so that the volume is set at said low preset volume level upon detecting human voices, and is set to said high preset volume level, if no human voices are detected, wherein the volume change from said high preset volume level to said low preset volume level is made in accordance to a first predetermined function of time, and the volume change from said low preset volume level to said high preset volume level is made in accordance to a second predetermined function of time.

2. The method of claim 1, wherein said first and second predetermined functions of time comprise at least one time segment, during which the volume level does not change and following it another time segment, during which the volume changes monotonically.

3. The method of claim 1, wherein at least one of said first and second predetermined functions of time is formed depending on parameters of detected human voice sounds.

4. The method of claim 1, wherein said checking for a human voice presence comprises a conversion of sounds within said monitored area into an observed signal and checking for speech features in said observed signal.

5. The method of claim 1, wherein said checking for a human voice presence comprises a conversion of sounds within said monitored area into an observed signal, a conversion of sounds within another area into an additional observed signal, and a comparison of said observed signal with said additional observed signal.

6. The method of claim 5, wherein said comparison of said observed signal with said additional observed signal comprises:
a detection of an envelope of said observed signal;
a detection of an envelope of said additional observed signal;
a first measuring of a level of said envelope of said observed signal in a predetermined frequency range;
a second measuring of a level of said envelope of said additional observed signal in said predetermined frequency range;
a comparison of results of said first measuring and said second measuring.

7. A system of volume control, comprising:
a sound-reproducing unit connected with a sound signal source;
a sound sensor;
an analysis and control unit, connected with said sound sensor and with said sound-reproducing unit, wherein said analysis and control unit is operative to detect human voice features in a signal received from said sound sensor, and to form a control signal providing the volume decrease in said sound-reproducing unit according to a first function of time to a preset low volume level upon detecting human voice features and the volume increase in said sound-reproducing unit according to a second function of time to a preset high volume level, when no human voice features are detected.

8. The system of claim 7, wherein said sound sensor is operative to control a sound level within a monitored area.

9. The system of claim 7, wherein said analysis and control unit comprises consecutively connected a feature detection unit, a measuring unit, and a control signal former.

10. The system of claim 9, wherein said feature detection unit comprises consecutively connected a band-pass filter, a detector, and a low-pass filter.

11. The system of claim 7, wherein said analysis and control unit is constructively displaced in a separate from said sound-reproducing unit housing.

12. The system of claim 11, wherein the housing of said analysis and control unit is the housing of a remote control device of said sound-reproducing unit.

13. The system of claim 7, wherein said analysis and control unit is additionally connected with said sound signal source and is operative to compare a signal received from said sound sensor to a signal received from said sound signal source, thereby to detect human voice features in the signal received from said sound sensor.

14. The system of claim 13, wherein said analysis and control unit comprises consecutively connected a subtraction unit, a feature detection unit, a measuring unit, and a control signal former.

15. The system of claim 14, wherein said feature detection unit comprises consecutively connected an envelope detector, a band-pass filter, a detector, and a low-pass filter.

16. The system of claim 7, further comprising an additional sound sensor, connected with said analysis and control unit, additionally operative to detect human voice features in the signal received from said sound sensor by comparing said signal with the signal received from said additional sound sensor.

17. The system of claim 16, wherein said analysis and control unit comprises a first and second detectors, a first and second measuring units, a comparison unit, and a control signal former, wherein said first measuring unit is connected with said first detector, said second measuring unit is connected with said second detector, said comparison unit is connected with said first measuring unit, said second measuring unit, and said control signal former.

18. The system of claim 17, wherein each of said first measuring unit and said second measuring unit comprises a band-pass filter, a first and second detectors, and a subtraction unit, wherein the input of said measuring unit is connected with said second detector and band-pass filter, which is connected with said first detector, and wherein said subtraction unit is connected with said first detector and said second detector.

19. A remote control device for sound-reproducing equipment, comprising consecutively connected a sound sensor, an analysis and control unit, a command forming unit, and a transmitter, wherein said analysis and control unit is operative to form on its output a first control signal upon detecting human voice features in the signal from said sound sensor and to form on its output a second control signal, when there are no human voice features in the signal from said sound sensor, and said command forming unit is operative to form at least one remote control command for decreasing volume upon receiving on its input said first control signal and to form at least one remote control command for increasing volume upon receiving on its input said second control signal.

20. The remote control device of claim 19, additionally comprising a reference signal receiver, connected with said analysis and control unit operative to detect voice features in the signal received from said sound sensor by the way of comparing said signal with a signal received from said reference signal receiver.

21. The remote control device of claim 19, further comprising an additional sound sensor, connected with said analysis and control unit operative to detect human voice features in the signal received from said sound sensor by comparing said signal with the signal received from said additional sound sensor.
